(19) United States
(12) Patent Application Publication
(10) Pub. No.: US 2025/0157918 A1
(43) Pub. Date: May 15, 2025

(54) SEMICONDUCTOR DEVICE AND INVERTER SYSTEM

(71) Applicant: Renesas Electronics Corporation, Tokyo (JP)

(72) Inventors: Yasutaka NAKASHIBA, Tokyo (JP); Takayuki IGARASHI, Tokyo (JP)

(21) Appl. No.: 18/925,247

(22) Filed: Oct. 24, 2024

(30) Foreign Application Priority Data
Nov. 15, 2023 (JP) 2023-194464

(51) Int. Cl. H01L 23/522; H01L 25/16; H02M 7/00

(52) U.S. Cl. CPC H01L 23/5227; H01L 25/16; H02M 7/003; H10D 1/20

(57) ABSTRACT

A semiconductor device includes a first semiconductor chip, a second semiconductor chip, and a third semiconductor chip. One of the first semiconductor chip and the second semiconductor chip includes a first switch. The other of the first semiconductor chip and the second semiconductor chip includes a second switch. The third semiconductor chip includes a first transformer. A signal is transmitted from the first semiconductor chip to the second semiconductor chip by the first transformer when the first switch is turned off while the second switch is turned on. A signal is transmitted from the second semiconductor chip to the first semiconductor chip by the first transformer when the second switch is turned off while the first switch is turned on.

### CROSS-REFERENCE TO RELATED APPLICATION

The disclosure of Japanese Patent Application No. 2023-194464 filed on Nov. 15, 2023, including the specification, drawings and abstract is incorporated herein by reference in its entirety.

### BACKGROUND

The present disclosure relates to a semiconductor device and an inverter system.

There is a disclosed technique listed below.
[Patent Document 1] International Patent Application Publication No. WO2014/097425

For example, Patent Document 1 describes a semiconductor device. The semiconductor device described in the Patent Document 1 includes a first semiconductor chip and a second semiconductor chip. The first semiconductor chip includes a first transmission circuit, a first reception circuit, and a first transformer. The second semiconductor chip includes a second transmission circuit, a second reception circuit, and a second transformer. In the semiconductor device described in the Patent Document 1, a signal is transmitted from the first semiconductor chip to the second semiconductor chip by the first transformer, and a signal is transmitted from the second semiconductor chip to the first semiconductor chip by the second transformer.

### SUMMARY

In the semiconductor device described in the Patent Document 1, since two transformers are required to transmit and receive the signals, a chip area increases. Other problems and novel characteristics will be apparent from the description of the specification and the accompanying drawings.

A semiconductor device according to the present disclosure includes a first semiconductor chip, a second semiconductor chip, and a third semiconductor chip. One of the first semiconductor chip and the second semiconductor chip includes a first switch. The other of the first semiconductor chip and the second semiconductor chip includes a second switch. The third semiconductor chip includes a first transformer. A signal is transmitted from the first semiconductor chip to the second semiconductor chip by the first transformer when the first switch is turned off while the second switch is turned on. A signal is transmitted from the second semiconductor chip to the first semiconductor chip by the first transformer when the second switch is turned off while the first switch is turned on.

According to the semiconductor device of the present disclosure, a chip area can be reduced.

### BRIEF DESCRIPTIONS OF THE DRAWINGS

FIG. 1 is a block diagram of a semiconductor device DEV;

FIG. 2 is an explanatory diagram illustrating an example of transmission of a signal from a semiconductor chip CHP1 to a semiconductor chip CHP2;

FIG. 3 is a first plan view of a semiconductor chip CHP3;

FIG. 4 is a second plan view of the semiconductor chip CHP3;

FIG. 5 is a third plan view of the semiconductor chip CHP3;

FIG. 6 is a cross-sectional view taken along a line VI-VI illustrated in FIG. 3;

FIG. 7 is a cross-sectional view taken along a line VII-VII illustrated in FIG. 3;

FIG. 8 is a block diagram of an inverter system INV;

FIG. 9 is a flowchart of manufacturing the semiconductor chip CHP3;

FIG. 10 is a cross-sectional view for explaining an ion implantation step S2;

FIG. 11 is a cross-sectional view for explaining a first-insulating-film formation step S3;

FIG. 12 is a cross-sectional view for explaining a first-via-plug formation step S4;

FIG. 13 is a cross-sectional view for explaining a first-wiring-layer formation step S5;

FIG. 14 is a cross-sectional view for explaining a second-insulating-film formation step S6;

FIG. 15 is a cross-sectional view for explaining a second-via-plug formation step S7;

FIG. 16 is a cross-sectional view for explaining a second-wiring-layer formation step S8;

FIG. 17 is a cross-sectional view for explaining a third-insulating-film formation step S9;

FIG. 18 is a cross-sectional view for explaining a third-via-plug formation step S10; and

FIG. 19 is a cross-sectional view for explaining a third-wiring-layer formation step S11.

### DETAILED DESCRIPTION

Details of embodiments of the present disclosure will be described with reference to the drawings. In the drawings described below, the same or corresponding components are denoted by the same reference signs, and overlapping description thereof is not repeated. A semiconductor device according to the embodiment is described as a semiconductor device DEV, and an inverter system according to the embodiment is described as an inverter system INV.

### (Configuration of Semiconductor Device DEV)

A configuration of the semiconductor device DEV will be described below.

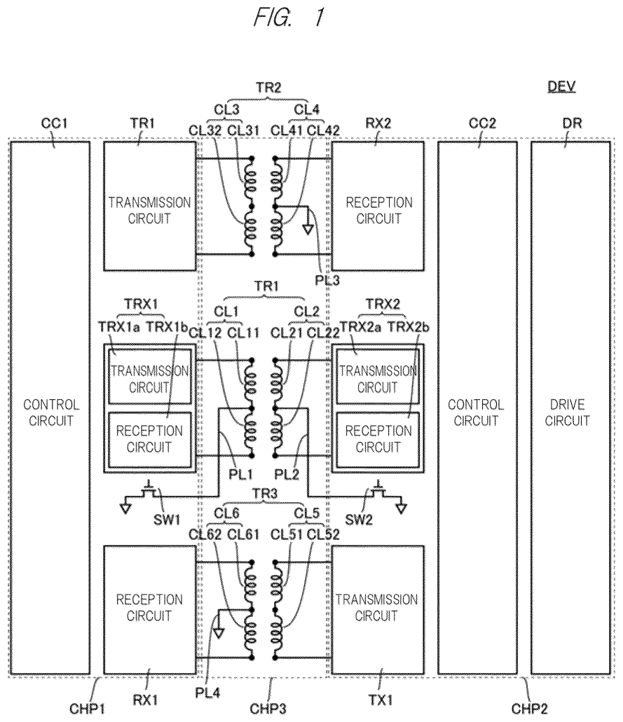

FIG. 1 is a block diagram of the semiconductor device DEV. As illustrated in FIG. 1, the semiconductor device DEV includes a semiconductor chip CHP1, a semiconductor chip CHP2, and a semiconductor chip CHP3.

The semiconductor chip CHP1 includes a transmission/reception circuit TRX1, a transmission circuit TX1, a reception circuit RX1, a switch SW1, and a control circuit CC1. The semiconductor chip CHP2 includes a transmission/reception circuit TRX2, a transmission circuit TX2, a reception circuit RX2, a switch SW2, a control circuit CC2, and a drive circuit DR. The semiconductor chip CHP3 includes a transformer TR1, a transformer TR2, and a transformer TR3, and a lead-out wiring PL1, a lead-out wiring PL2, a lead-out wiring PL3, and a lead-out wiring PL4. The transmission/reception circuit TRX1 includes a transmission circuit TRX1a and a reception circuit TRX1b. The transmission/reception circuit TRX2 includes a transmission circuit TRX2a and a reception circuit TRX2b.

The transformer TR1 includes a transmission/reception coil CL1 and a transmission/reception coil CL2. The transmission/reception coil CL1 and the transmission/reception coil CL2 are respectively electrically connected to the transmission/reception circuit TRX1 and the transmission/reception circuit TRX2. The transmission/reception coil CL1 includes a coil CL11 and a coil CL12. The coil CL11 and the coil CL12 are electrically connected in series with each other through the lead-out wiring PL1. The transmission/reception coil CL2 includes a coil CL21 and a coil CL22. The coil CL21 and the coil CL22 are electrically connected in series with each other through the lead-out wiring PL2.

The lead-out wiring PL1 is electrically connected to the switch SW1. The switch SW1 is connected to a ground potential. Accordingly, when the switch SW1 is turned on, the lead-out wiring PL1 is electrically connected to the ground potential. The lead-out wiring PL2 is electrically connected to the switch SW2. The switch SW2 is connected to the ground potential. Accordingly, when the switch SW2 is turned on, the lead-out wiring PL2 is electrically connected to the ground potential. Each of the switch SW1 and the switch SW2 is, for example, a MOSFET (Metal Oxide Semiconductor Field Effect Transistor). Each of a gate width of the MOSFET configuring the switch SW1 and a gate width of the MOSFET configuring the switch SW2 may be, for example, equal to or larger than 5 μm in order to reduce a loss due to an on resistance. When the gate of the one MOSFET is divided to stabilize its gate potential, the gate width is the sum of the divided-gate widths. Each of a gate width of the MOSFET configuring the switch SW1 and a gate width of the MOSFET configuring the switch SW2 may be, for example, equal to or larger than 0.5 μm in order to reduce a loss caused by a leak.

The transformer TR2 includes a transmission coil CL3 and a reception coil CL4. The transmission coil CL3 and the reception coil CL4 are respectively electrically connected to the transmission circuit TX1 and the reception circuit RX2. The transmission coil CL3 includes a coil CL31 and a coil CL32. The coil CL31 and the coil CL32 are electrically connected in series with each other. The reception coil CL4 includes a coil CL41 and a coil CL42. The coil CL41 and the coil CL42 are electrically connected in series with each other through the lead-out wiring PL3.

The transformer TR3 includes a transmission coil CL5 and a reception coil CL6. The transmission coil CL5 and the reception coil CL6 are respectively electrically connected to the transmission circuit TX2 and the reception circuit RX1. The transmission coil CL5 includes a coil CL51 and a coil CL52. The coil CL51 and the coil CL52 are electrically connected in series with each other. The reception coil CL6 includes a coil CL61 and a coil CL62. The coil CL61 and the coil CL62 are electrically connected in series with each other through the lead-out wiring PL4.

Although not illustrated, the control circuit CC1 is electrically connected to the transmission/reception circuit TRX1, the transmission circuit TX1, the reception circuit RX1, and the switch SW1, and the control circuit CC2 is electrically connected to the transmission/reception circuit TRX2, the transmission circuit TX2, the reception circuit RX2, and the switch SW2. Although not illustrated, the drive circuit DR is electrically connected to the control circuit CC2.

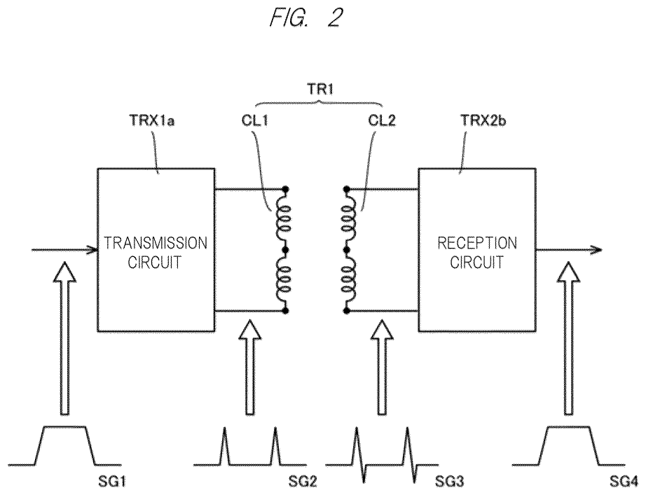

FIG. 2 is an explanatory diagram illustrating an example of transmission of a signal from the semiconductor chip CHP1 to the semiconductor chip CHP2. As illustrated in FIG. 2, first, the control circuit CC1 turns off the switch SW1, and the control circuit CC2 turns on the switch SW2. As a result, the transmission/reception coil CL1 functions as a transmission coil, and the transmission/reception coil CL2 functions as a reception coil. In this case, the control circuit CC1 electrically connects the transmission circuit TRX1a to the transmission/reception coil CL1, and the control circuit CC2 electrically connects the reception circuit TRX2b to the transmission/reception coil CL2.

Second, the control circuit CC1 outputs a signal SG1 to the transmission/reception circuit TRX1 (the transmission circuit TRX1a). The signal SG1 is a square wave. The transmission circuit TRX1a modulates the signal SG1 into a signal SG2, and transmits the signal SG2 to the transmission/reception coil CL1. When the signal SG2 flows through the transmission/reception coil CL1, a signal SG3 corresponding to the signal SG2 flows through the transmission/reception coil CL2 by an induced electromotive force. The transmission/reception circuit TRX2 (the reception circuit TRX2b) amplifies the signal SG3, and demodulates the signal SG3 into a square wave.

When a signal is transmitted from the semiconductor chip CHP2 to the semiconductor chip CHP1, the control circuit CC1 turns on the switch SW1, and the control circuit CC2 turns off the switch SW2. As a result, the transmission/reception coil CL1 functions as a reception coil, and the transmission/reception coil CL2 functions as a transmission coil. In this case, the control circuit CC1 electrically connects the reception circuit TRX1b to the transmission/reception coil CL1, and the control circuit CC2 electrically connects the transmission circuit TRX2a to the transmission/reception coil CL2. In other regards, the signal is similarly transmitted from the semiconductor chip CHP2 to the semiconductor chip CHP1 by the transformer TR1.

Thus, the signal transmission from the semiconductor chip CHP1 to the semiconductor chip CHP2 and the signal transmission from the semiconductor chip CHP2 to the semiconductor chip CHP1 by the transformer TR1 are performed in a pulse communication mode. More specifically, these signal transmissions are performed in an SPI (Serial Peripheral Interface) communication mode.

Even in signal transmission from the semiconductor chip CHP1 to the semiconductor chip CHP2 by the transformer TR2, the signal is also outputted from the control circuit CC1 to the transmission circuit TX1, is transmitted to the transmission coil CL3, and flows through the reception coil CL4 by an induced electromotive force. The signal flowing through the reception coil CL4 is amplified and demodulated by the reception circuit RX2, and then, is received.

Note that the control circuit CC2 drives the drive circuit DR on the basis of the signal received by the reception circuit RX2. That is, the signal transmission from the semiconductor chip CHP1 to the semiconductor chip CHP2 by the transformer TR2 is also performed in the pulse communication mode. More specifically, the signal transmission is performed in a PWM (Pulse Width Modulation) communication mode. Signal transmission from the semiconductor chip CHP2 to the semiconductor chip CHP1 by the transformer TR3 is also performed similarly to the signal transmission from the semiconductor chip CHP1 to the semiconductor chip CHP2 by the transformer TR2.

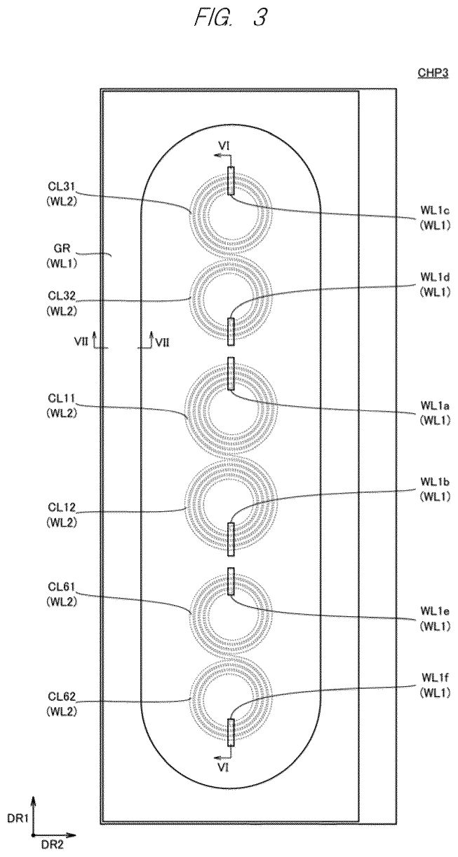

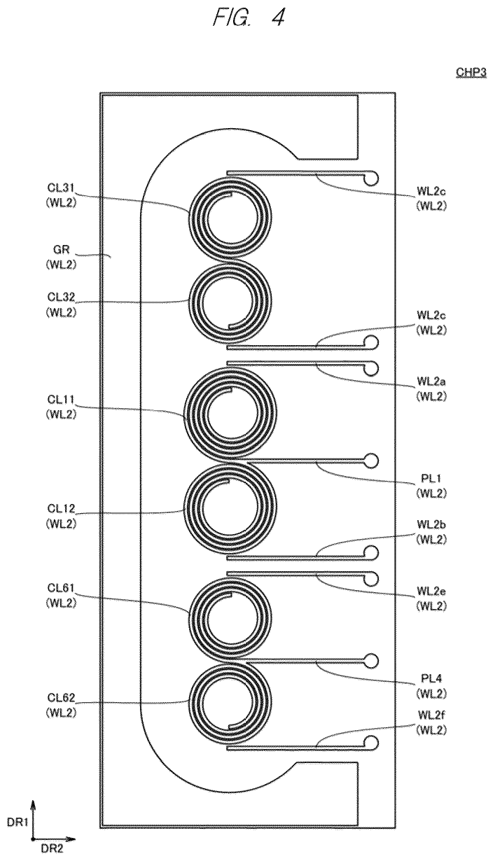

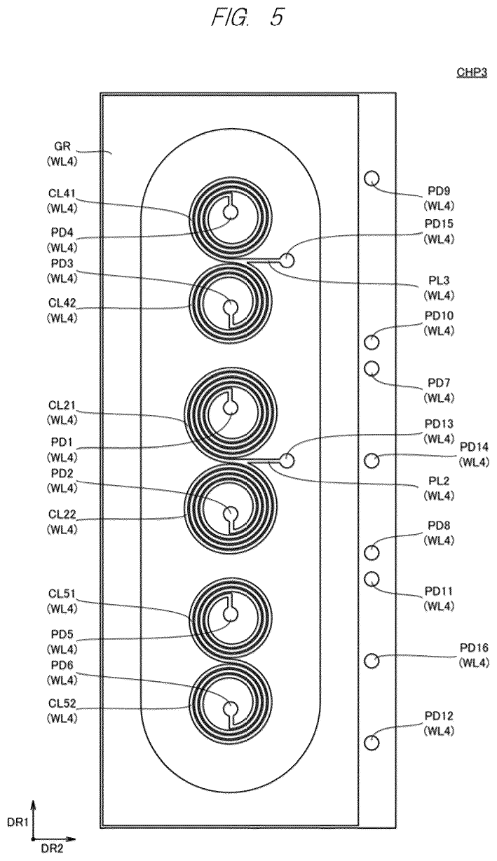

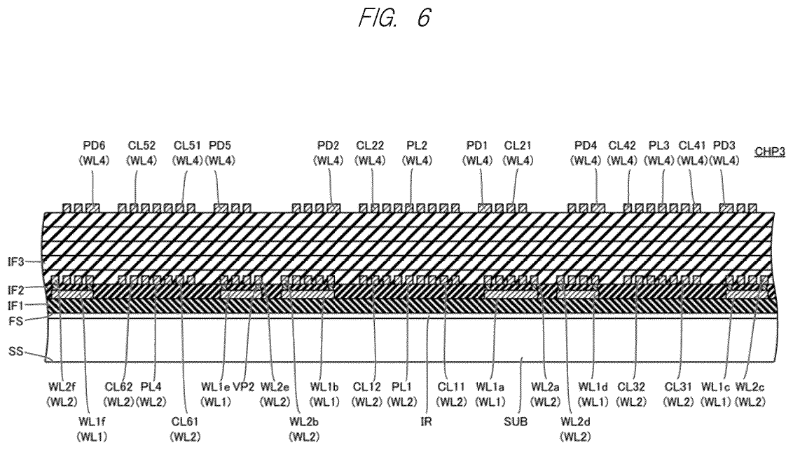

FIG. 3 is a first plan view of the semiconductor chip CHP3. FIG. 4 is a second plan view of the semiconductor chip CHP3. FIG. 5 is a third plan view of the semiconductor chip CHP3. FIG. 6 is a cross-sectional view taken along a line VI-VI illustrated in FIG. 3. As illustrated in FIGS. 3 to 6, the semiconductor chip CHP3 further includes a semiconductor substrate SUB.

The semiconductor substrate SUB has a first surface FS and a second surface SS. The second surface SS is an opposite surface of the first surface FS. The first surface FS and the second surface SS are each an end surface of the semiconductor substrate SUB in a thickness direction. A material configuring the semiconductor substrate SUB is, for example, single crystal silicon. The semiconductor substrate SUB includes an impurity implantation region IR. The impurity implantation region IR is formed at the first surface FS. A conductivity type of the semiconductor substrate SUB is, for example, a p-type. A dopant concentration in the impurity implantation region IR is higher than a dopant concentration outside the impurity implantation region IR.

The semiconductor chip CHP3 further includes an insulating film IF1. The insulating film IF1 is arranged on the semiconductor substrate SUB. More specifically, the insulating film IF1 is arranged on the first surface FS. A material configuring the insulating film IF1 is, for example, a silicon oxide.

The semiconductor chip CHP3 further includes a wiring layer WL1. The wiring layer WL1 is arranged on the insulating film IF1. The wiring layer WL1 includes a wiring WL1a, a wiring WL1b, a wiring WL1c, a wiring WL1d, a wiring WL1e, and a wiring WL1f. The wiring WL1a, the wiring WL1b, the wiring WL1c, the wiring WL1d, the wiring WL1e, and the wiring WL1f extend in a first direction DR1 in plan view. A material configuring the wiring layer WL1 is, for example, a conductive material containing aluminum as a main component.

The semiconductor chip CHP3 further includes an insulating film IF2. The insulating film IF2 is arranged on the insulating film IF1 to cover the wiring layer WL1. A material configuring the insulating film IF2 is, for example, a silicon oxide.

The semiconductor chip CHP3 further includes a wiring layer WL2. The wiring layer WL2 is arranged on the insulating film IF2. The wiring layer WL2 includes a transmission/reception coil CL1 (a coil CL11 and a coil CL12), a transmission coil CL3 (a coil CL31 and a coil CL32), a reception coil CL6 (a coil CL61 and a coil CL62), a wiring WL2a, a wiring WL2b, a wiring WL2c, a wiring WL2d, a wiring WL2e, a wiring WL2f, a lead-out wiring PL1, and a lead-out wiring PL4. A material configuring the wiring layer WL2 is, for example, a conductive material containing aluminum as a main component.

The coil CL11 and the coil CL12 are adjacent to each other in the first direction DR1. The coil CL11 and the coil CL12 are spirally wound in plan view. More specifically, in an example illustrated in FIG. 4, the coil CL11 is wound counterclockwise in a direction from its innermost periphery toward its outermost periphery in plan view, and the coil CL12 is spirally wound clockwise in a direction from its outermost periphery toward its innermost periphery in plan view. The coil CL11 and the coil CL12 are electrically connected in series with each other through the lead-out wiring PL1. More specifically, an end of an outermost periphery of the coil CL11 is connected to an end of an outermost periphery of the coil CL12 through one end of the lead-out wiring PL1.

The coil CL31 and the coil CL32 are adjacent to each other in the first direction DR1. The coil CL31 and the coil CL32 are spirally wound in plan view. More specifically, in the example illustrated in FIG. 4, the coil CL31 is wound counterclockwise in a direction from its innermost periphery toward its outermost periphery in plan view, and the coil CL32 is spirally wound clockwise in a direction from its outermost periphery toward its innermost periphery in plan view. The coil CL31 and the coil CL32 are electrically connected in series with each other. More specifically, an end of an outermost periphery of the coil CL31 is connected to an end of an outermost periphery of the coil CL32.

The coil CL61 and the coil CL62 are adjacent to each other in the first direction DR1. The coil CL61 and the coil CL62 are spirally wound in plan view. More specifically, in the example illustrated in FIG. 4, the coil CL61 is wound counterclockwise in a direction from its innermost periphery toward its outermost periphery in plan view, and the coil CL62 is spirally wound clockwise in a direction from its outermost periphery toward its innermost periphery in plan view. The coil CL61 and the coil CL62 are electrically connected in series with each other through the lead-out wiring PL4. More specifically, an end of an outermost periphery of the coil CL61 is connected to an end of an outermost periphery of the coil CL62 through one end of the lead-out wiring PL4.

The transmission/reception coil CL1, the transmission coil CL3 and the reception coil CL6 are arranged side by side in the first direction DR1. In the first direction DR1, the transmission/reception coil CL1 is arranged between the transmission coil CL3 and the reception coil CL6.

The wiring WL2a, the wiring WL2b, the wiring WL2c, the wiring WL2d, the wiring WL2e, and the wiring WL2f extend in a second direction DR2 in plan view. The second direction DR2 is a direction perpendicular to the first direction DR1 in plan view. One end of the wiring WL2a and one end of the wiring WL2b are respectively adjacent to the coil CL11 and the coil CL12. One end of the wiring WL2c and one end of the wiring WL2d are respectively adjacent to the coil CL31 and the coil CL32. One end of the wiring WL2ce and one end of the wiring WL2f are respectively adjacent to the coil CL61 and the coil CL62.

The one end of the wiring WL2a and an end of the innermost periphery of the coil CL11 are electrically connected to each other by the wiring WL1a and a via plug VP2, and the one end of the wiring WL2b and an end of the innermost periphery of the coil CL12 are electrically connected to each other by the wiring WL1b and the via plug VP2. The one end of the wiring WL2c and an end of the innermost periphery of the coil CL31 are electrically connected to each other by the wiring WL1c and the via plug VP2, and the one end of the wiring WL2d and an end of the innermost periphery of the coil CL32 are electrically connected to each other by the wiring WL1d and the via plug VP2.

The one end of the wiring WL2e and an end of the innermost periphery of the coil CL61 are electrically connected to each other by the wiring WL1e and the via plug VP2, and the one end of the wiring WL2f and an end of the innermost periphery of the coil CL62 are electrically connected to each other by the wiring WL1f and the via plug VP2. The via plug VP2 is embedded in the insulating film IF2. A material configuring the via plug VP2 is, for example, a conductive material containing tungsten as a main component.

The semiconductor chip CHP3 further includes a plurality of insulating films IF3. The plurality of insulating films IF3 are stacked. The insulating film IF3 as the lowermost layer is arranged on the insulating film IF2 to cover the wiring layer WL2. A material configuring the insulating film IF3 is, for example, a silicon oxide. The semiconductor chip CHP3 further includes a plurality of wiring layers WL3. Each of the wiring layers WL3 is arranged on one insulating film IF3, and is covered with the other insulating film IF3 on the one insulating film IF3.

The semiconductor chip CHP3 further includes a wiring layer WL4. The wiring layer WL4 includes a transmission/reception coil CL2 (a coil CL21 and a coil CL22), a reception coil CL4 (a coil CL41 and a coil CL42), a transmission coil CL5 (a coil CL51 and a coil CL52), a lead-out wiring PL2, and a lead-out wiring PL3. A material configuring the wiring layer WL4 is, for example, a conductive material containing aluminum as a main component.

The coil CL21 and the coil CL22 are adjacent to each other in the first direction DR1. The coil CL21 and the coil CL22 are spirally wound in plan view. More specifically, in an example illustrated in FIG. 5, the coil CL21 is wound counterclockwise in a direction from its innermost periphery toward its outermost periphery in plan view, and the coil CL22 is spirally wound clockwise in a direction from its outermost periphery toward its innermost periphery in plan view. The coil CL21 and the coil CL22 are electrically connected in series with each other through the lead-out wiring PL2. More specifically, an end of an outermost periphery of the coil CL21 is connected to an end of an outermost periphery of the coil CL22 through one end of the lead-out wiring PL2.

The coil CL41 and the coil CL42 are adjacent to each other in the first direction DR1. The coil CL41 and the coil CL42 are spirally wound in plan view. More specifically, in the example illustrated in FIG. 5, the coil CL41 is wound counterclockwise in a direction from its innermost periphery toward its outermost periphery in plan view, and the coil CL42 is spirally wound clockwise in a direction from its outermost periphery toward its innermost periphery in plan view. The coil CL41 and the coil CL42 are electrically connected in series with each other through the lead-out wiring PL3. More specifically, an end of an outermost periphery of the coil CL41 is connected to an end of an outermost periphery of the coil CL42 through one end of the lead-out wiring PL3.

The coil CL51 and the coil CL52 are adjacent to each other in the first direction DR1. The coil CL51 and the coil CL52 are spirally wound in plan view. More specifically, in the example illustrated in FIG. 5, the coil CL51 is wound counterclockwise in a direction from its innermost periphery toward its outermost periphery in plan view, and the coil CL52 is spirally wound clockwise in a direction from its outermost periphery toward its innermost periphery in plan view. The coil CL51 and the coil CL52 are electrically connected in series with each other. More specifically, an end of an outermost periphery of the coil CL51 is connected to an end of an outermost periphery of the coil CL52.

The wiring layer WL4 further includes a pad PD1, a pad PD2, a pad PD3, a pad PD4, a pad PD5, and a pad PD6. The pad PD1 and the pad PD2 are respectively connected to an end of the innermost periphery of the coil CL21 and an end of the innermost periphery of the coil CL22. The pad PD3 and the pad PD4 are respectively connected to an end of the innermost periphery of the coil CL41 and an end of the innermost periphery of the coil CL42. The pad PD5 and the pad PD6 are respectively connected to an end of the innermost periphery of the coil CL51 and an end of the innermost periphery of the coil CL52.

The wiring layer WL4 further includes a pad PD7, a pad PD8, a pad PD9, a pad PD10, a pad PD11, and a pad PD12. The pad PD7 and the pad PD8 are respectively electrically connected to the other end of the wiring WL2a and the other end of the wiring WL2b by the wiring layer WL4 and a via plug VP3. The pad PD9 and the pad PD10 are respectively electrically connected to the other end of the wiring WL2c and the other end of the wiring WL2d by the wiring layer WL4 and the via plug VP3. The pad PD11 and the pad PD12 are respectively electrically connected to the other end of the wiring WL2e and the other end of the wiring WL2f by the wiring layer WL4 and the via plug VP3. The via plug VP3 is embedded in the insulating film IF3. A material configuring the via plug VP3 is, for example, a conductive material containing tungsten as a main component.

The wiring layer WL4 further includes a pad PD13, a pad PD14, a pad PD15, and a pad PD16. The pad PD13 and the pad PD14 are respectively connected to the other end of the lead-out wiring PL2 and the other end of the lead-out wiring PL3. The pad PD15 is electrically connected to the other end of the lead-out wiring PL1 by the wiring layer WL3 and the via plug VP3. The pad PD16 is electrically connected to the other end of the lead-out wiring PL4 by the wiring layer WL3 and the via plug VP3.

In the pad PD1, the pad PD2, the pad PD3, the pad PD4, the pad PD5, the pad PD6, the pad PD13, and the pad PD14, the semiconductor chip CHP3 is electrically connected to the semiconductor chip CHP2. In the pad PD7, the pad PD8, the pad PD9, the pad PD10, the pad PD11, the pad PD12, the pad PD15, and the pad PD16, the semiconductor chip CHP3 is electrically connected to the semiconductor chip CHP1.

The wiring layer WL4 is arranged on the insulating film IF3 as the uppermost layer. The transmission/reception coil CL2 overlaps the transmission/reception coil CL1 in plan view. The reception coil CL4 overlaps the transmission coil CL3 in plan view. The transmission coil CL5 overlaps the reception coil CL6 in plan view. Accordingly, the transmission/reception coil CL2, the reception coil CL4, and the transmission coil CL5 are respectively arranged to face the transmission/reception coil CL1, the transmission coil CL3, and the reception coil CL6 through insulating layers (the plurality of insulating films IF3).

As described above, the transmission/reception coil CL1, the transmission coil CL3, and the reception coil CL6 are arranged side by side in the first direction DR1 such that the transmission/reception coil CL1 is positioned between the transmission coil CL3 and the reception coil CL4. Accordingly, the transformer TR1, the transformer TR2, and the transformer TR3 are arranged side by side in the first direction DR1 such that the transformer TR1 is positioned between the transformer TR2 and the transformer TR3.

The number of coil windings of the transformer TR1 is larger than, for example, the number of coil windings of the transformer TR2 and the number of coil windings of the transformer TR3. The number of coil windings of the transformer is defined as the number of windings of the coil included in the transformer. For example, the number of coil windings of the transformer TR1 is the number of windings of the coil CL11 (the coil CL12, the coil CL21, the coil CL22). When the number of coil windings included in the transformer is equal to or larger than “n” and smaller than “(n+1)”, the number of coil windings is regarded as “(n+1)”. The number of coil windings of the transformer TR1 is, for example, one or two larger than the number of coil windings of the transformer TR2 and the number of coil windings of the transformer TR3.

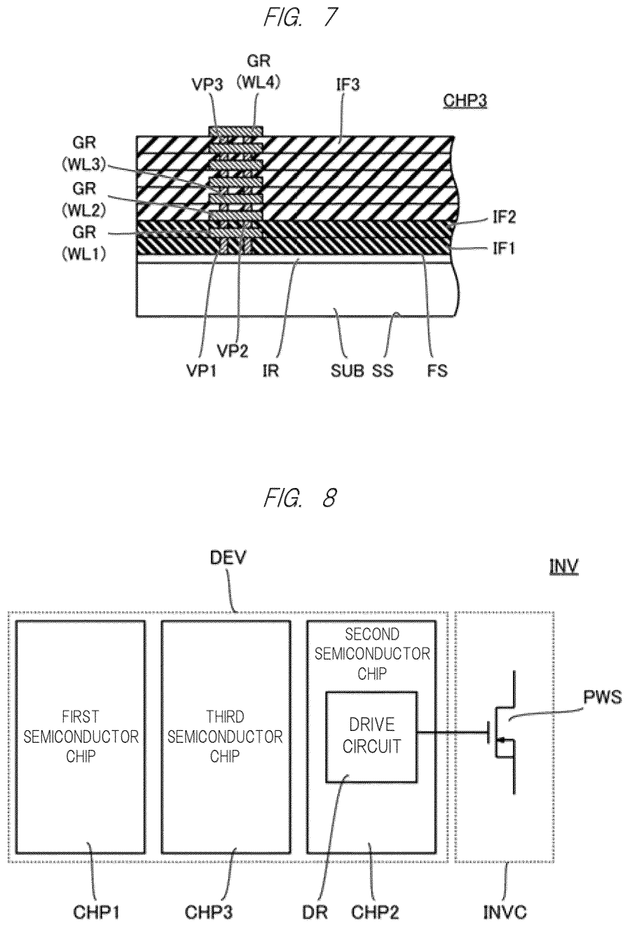

FIG. 7 is a cross-sectional view taken along a line VII-VII illustrated in FIG. 3. As illustrated in FIG. 7, the semiconductor chip CHP3 further includes a guard ring GR. The guard ring GR surrounds the transformer TR1, the transformer TR2, and the transformer TR3 in plan view.

The guard ring GR is made of the wiring layer WL4, the wiring layer WL3, the wiring layer WL2, the wiring layer WL1, the via plug VP1, the via plug VP2, and the via plug VP3. In the guard ring GR, by the via plug VP3, the wiring layer WL4 and the wiring layer WL3 as the uppermost layer are connected to each other, the stacked wiring layers WL3 are connected to each other, and the wiring layer WL3 as the lowermost layer and the wiring layer WL2 are connected to each other. In the guard ring GR, the wiring layer WL2 and the wiring layer WL1 are connected to each other by the via plug VP2, and the wiring layer WL1 and the semiconductor substrate SUB are connected to each other by the via plug VP1. The via plug VP1 is embedded in the insulating film IF1. A material configuring the via plug VP1 is, for example, a conductive material containing tungsten as a main component.

Each of a distance between the transformer TR1 and the transformer TR2 in plan view and a distance between the transformer TR1 and the transformer TR3 in plan view is, for example, equal to or larger than 15 μm. Each of a distance between the transformer TR1 and the guard ring GR in plan view, a distance between the transformer TR2 and the guard ring GR in plan view, and a distance between the transformer TR3 and the guard ring GR in plan view is, for example, equal to or larger than 50 μm.

Although not illustrated, the semiconductor chip CHP3 further includes a passivation film. The passivation film is arranged on the insulating film IF3 as the uppermost layer to cover the wiring layer WL4. In the passivation film, an opening is formed to expose the pad PD1 to the pad PD16.

FIG. 8 is a block diagram of an inverter system INV. As illustrated in FIG. 8, the inverter system INV includes the semiconductor device DEV and an inverter circuit INVC. The inverter circuit INVC includes a switching circuit configured by a plurality of power semiconductor elements PWS. The power semiconductor element PWS is an IGBT (insulated gate bipolar transistor), for example. The power semiconductor element PWS is driven by the drive circuit DR.

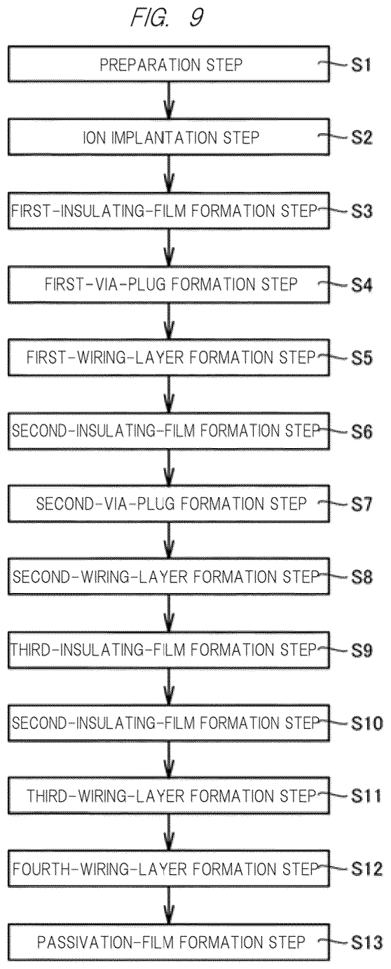

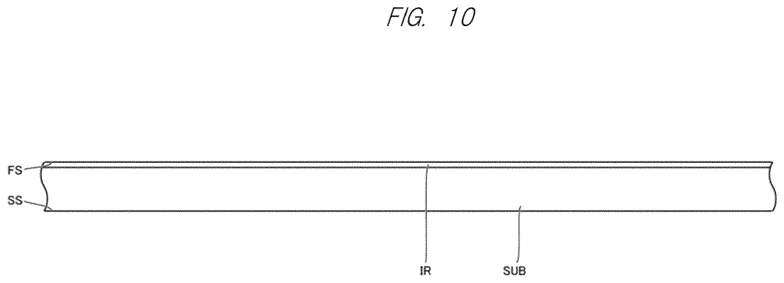

FIG. 9 is a flowchart of manufacturing the semiconductor chip CHP3. As illustrated in FIG. 9, the method of manufacturing the semiconductor chip CHP3 includes a preparation step S1, an ion implantation step S2, a first-insulating-film formation step S3, a first-via-plug formation step S4, a first-wiring-layer formation step S5, and a second-insulating-film formation step S6. The method of manufacturing the semiconductor chip CHP3 further includes a second-via-plug formation step S7, a second-wiring-layer formation step S8, a third-insulating-film formation step S9, a third-via-plug formation step S10, a third-wiring-layer formation step S11, a fourth-wiring-layer formation step S12, and a passivation-film formation step S13.

In the preparation step S1, the semiconductor substrate SUB is prepared. After the preparation step S1, the ion implantation step S2 is performed. FIG. 10 is a cross-sectional view for explaining the ion implantation step S2. As illustrated in FIG. 10, when the ion implantation is performed in the ion implantation step S2, the impurity implantation region IR is formed. After the ion implantation step S2, the first-insulating-film formation step S3 is performed.

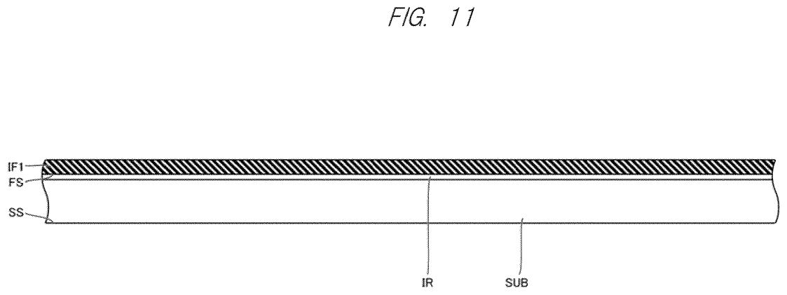

FIG. 11 is a cross-sectional view for explaining the first-insulating-film formation step S3. As illustrated in FIG. 11, in the first-insulating-film formation step S3, the insulating film IF1 is formed on the semiconductor substrate SUB by, for example, a CVD (Chemical Vapor Deposition) method. After the first-insulating-film formation step S3, the first-via-plug formation step S4 is performed.

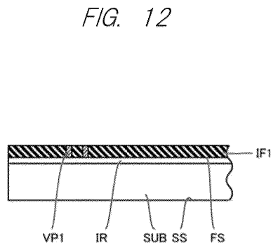

FIG. 12 is a cross-sectional view for explaining the first-via-plug formation step S4. As illustrated in FIG. 12, in the first-via-plug formation step S4, the via plug VP1 is embedded in the insulating film IF1. In the first-via-plug formation step S4, firstly, a via hole is formed in the insulating film IF1 by dry etching using a resist pattern formed by a photolithography method as a mask. Secondly, a material configuring the via plug VP1 is embedded in the via hole by, for example, a CVD method. Thirdly, a material configuring the via plug VP1, which protrudes from the via hole, is removed by, for example, a CMP (Chemical Mechanical Polishing) method. After the first-via-plug formation step S4, the first-wiring-layer formation step S5 is performed.

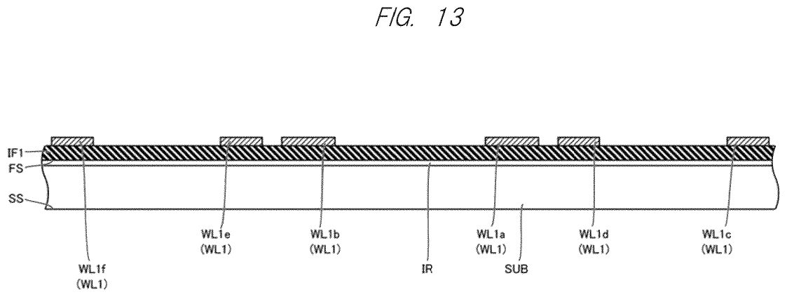

FIG. 13 is a cross-sectional view for explaining the first-wiring-layer formation step S5. As illustrated in FIG. 13, in the first-wiring-layer formation step S5, the wiring layer WL1 is formed on the insulating film IF1. In the first-wiring-layer formation step S5, firstly, a material configuring the wiring layer WL1 is formed by, for example, a sputtering method. Secondly, the material configuring the formed wiring layer WL1 is patterned by, for example, dry etching using a resist pattern formed by a photolithography method as a mask. After the first-wiring-layer formation step S5, the second-insulating-film formation step S6 is performed.

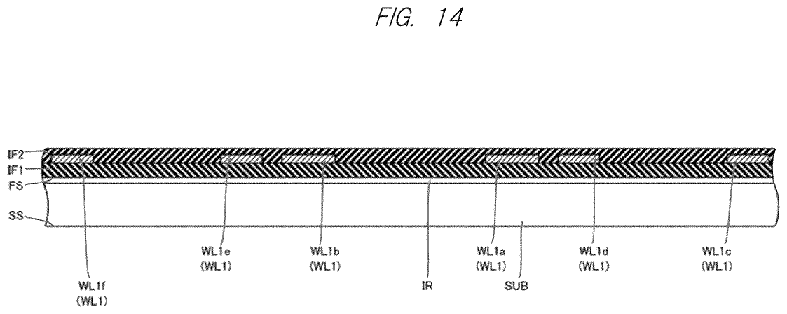

FIG. 14 is a cross-sectional view for explaining the second-insulating-film formation step S6. As illustrated in FIG. 14, in the second-insulating-film formation step S6, the insulating film IF2 is formed on the insulating film IF1 to cover the wiring layer WL1. In the second-insulating-film formation step S6, firstly, a material configuring the insulating film IF2 is formed by, for example, a CVD method. Secondly, the material configuring the formed insulating film IF2 is flattened by, for example, a CMP method. After the second-insulating-film formation step S6, the second-via-plug formation step S7 is performed.

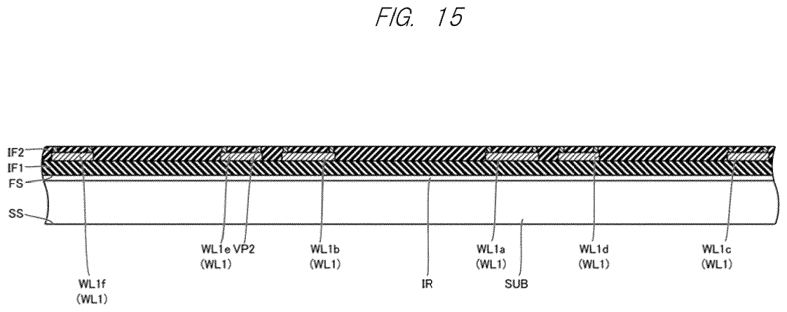

FIG. 15 is a cross-sectional view for explaining the second-via-plug formation step S7. As illustrated in FIG. 15, in the second-via-plug formation step S7, the via plug VP2 is embedded in the insulating film IF2 by a similar method to that in the first-via-plug formation step S4. After the second-via-plug formation step S7, the second-wiring-layer formation step S8 is performed.

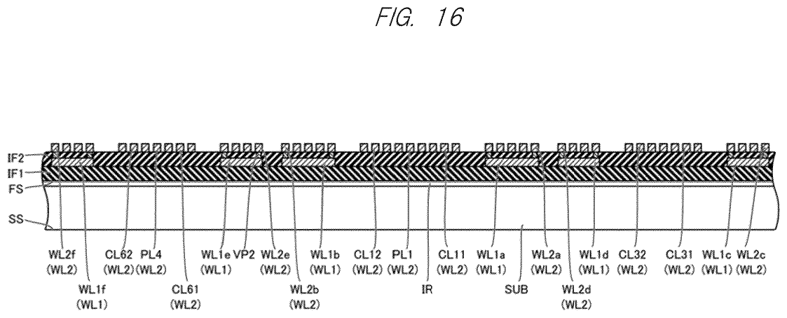

FIG. 16 is a cross-sectional view for explaining the second-wiring-layer formation step S8. As illustrated in FIG. 16, in the second-wiring-layer formation step S8, the wiring layer WL2 is formed on the insulating film IF2. In the second-wiring-layer formation step S8, firstly, a material configuring the wiring layer WL2 is formed by, for example, sputtering. Secondly, the material configuring the formed wiring layer WL2 is patterned by, for example, dry etching using a resist pattern formed by a photolithography method as a mask. After the second-wiring-layer formation step S8, the third-insulating-film formation step S9 is performed.

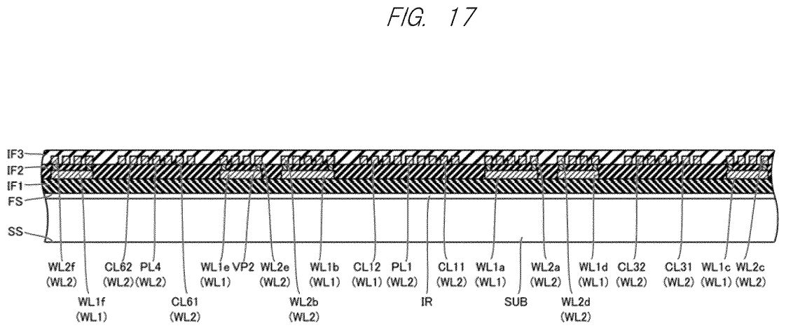

FIG. 17 is a cross-sectional view for explaining the third-insulating-film formation step S9. As illustrated in FIG. 17, in the third-insulating-film formation step S9, the insulating film IF3 is formed on the insulating film IF2 to cover the wiring layer WL2. After the third-insulating-film formation step S9, the third-via-plug formation step S10 is performed.

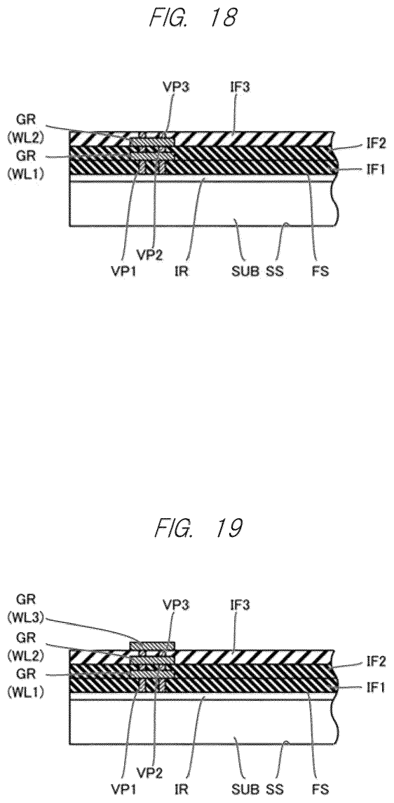

FIG. 18 is a cross-sectional view for explaining the third-via-plug formation step S10. As illustrated in FIG. 18, in the third-via-plug formation step S10, the via plug VP3 is embedded in the insulating film IF3 by a similar method to that in the second-via-plug formation step S7. After the third-via-plug formation step S10, the third-wiring-layer formation step S11 is performed.

FIG. 19 is a cross-sectional view for explaining the third-wiring-layer formation step S11. As illustrated in FIG. 19, in the third-wiring-layer formation step S11, the wiring layer WL3 is formed by a similar method to that in the second-wiring-layer formation step S8. Until the insulating film IF3 as the uppermost layer is formed, the third-insulating-film formation step S9, the third-via-plug formation step S10, and the third-wiring-layer formation step S11 are repeated. After the insulating film IF3 as the uppermost layer is formed, the fourth-wiring-layer formation step S12 is performed.

FIG. 20 is a cross-sectional view for explaining the fourth-wiring-layer formation step S12. In the fourth-wiring-layer formation step S12, the wiring layer WL4 is formed on the insulating film IF3 as the uppermost layer by a similar method to that in the second-wiring-layer formation step S8. After the fourth-wiring-layer formation step S12, the passivation-film formation step S13 is performed.

In the passivation-film formation step S13, the passivation film PF is formed on the insulating film IF3 as the uppermost layer to cover the wiring layer WL4. In the passivation-film formation step S13, firstly, a material configuring the passivation film is formed by, for example, a CVD method. Secondly, the material configuring the passivation film is patterned by, for example, dry etching using a resist pattern formed by a photolithography method as a mask. When division into pieces is performed by dicing or the like after the foregoing steps, a structure of the semiconductor chip CHP3 illustrated in FIGS. 3 to 7 is formed.

### <Effect of Semiconductor Device DEV>

An effect of the semiconductor device DEV will be described below.

In the semiconductor device DEV, by switching of the switch SW1 and switching of the switch SW2, one of the transmission/reception coil CL1 and the transmission/reception coil CL2 can be functioned as a transmission coil while the other of the transmission/reception coil CL1 and the transmission/reception coil CL2 can be functioned as a reception coil. Accordingly, the respective functions of two transformers can be performed by the transformer TR1, and thus, the chip area can be reduced.

In the semiconductor device DEV, the switch SW1 and the switch SW2 are not formed on the semiconductor chip CHP3 but formed on each of the semiconductor chip CHP1 and the semiconductor chip CHP2. Accordingly, in the semiconductor device DEV, it is unnecessary to apply a CMOS (Complementary Metal Oxide Semiconductor) process to the semiconductor chip CHP3, and the steps of manufacturing the semiconductor chip CHP3 can be simplified.

By increase in the number of coil windings of the transformer TR1, a coupling coefficient between the transmission/reception coil CL1 and the transmission/reception coil CL2 is improved, and a loss caused by the signal transmission is reduced. In the semiconductor device DEV, a loss may be caused by respective resistances of the switch SW1 and the switch SW2. However, by increase in the number of coil windings of the transformer TR1 to be larger than the number of coil windings of the transformer TR2 and the number of coil windings of the transformer TR3, the loss caused by the respective resistances of the switch SW1 and the switch SW2 can be canceled.

On the other hand, if the number of coil windings of the transformer TR1 is made excessively larger than the number of coil windings of the transformer TR2 and the number of coil windings of the transformer TR3, the chip area is undesirably large. Accordingly, when the number of coil windings of the transformer TR1 is equal to or smaller than 1.2 times the number of coil windings of the transformer TR2 and the number of coil windings of the transformer TR3, the chip area can be reduced while the loss caused by the respective resistances of the switch SW1 and the switch SW2 can be canceled.

In the semiconductor device DEV, the transformer TR1 is arranged between the transformer TR2 and the transformer TR3 in plan view. Accordingly, the distance between the transmission coil CL3 and the transmission coil CL5 and the distance between the reception coil CL4 and the reception coil CL6 are large. As a result, according to the semiconductor device DEV, a crosstalk between the transformer TR2 and the transformer TR3 can be suppressed.

In the foregoing, the invention made by the inventors of the present application has been concretely described on the basis of the embodiments. However, it is needless to say that the present invention is not limited to the foregoing embodiments, and various modifications can be made within the scope of the present invention.

What is claimed is:

1. A semiconductor device comprising:
a first semiconductor chip;
a second semiconductor chip; and
a third semiconductor chip,
wherein one of the first semiconductor chip and the second semiconductor chip includes a first switch,
wherein the other of the first semiconductor chip and the second semiconductor chip includes a second switch,
wherein the third semiconductor chip includes a first transformer,
wherein a signal is transmitted from the first semiconductor chip to the second semiconductor chip by the first transformer when the first switch is turned off while the second switch is turned on, and
wherein a signal is transmitted from the second semiconductor chip to the first semiconductor chip by the first transformer when the second switch is turned off while the first switch is turned on.

2. The semiconductor device according to claim 1,
wherein the third semiconductor chip includes:
a semiconductor substrate;
a first transmission/reception coil and a second transmission/reception coil configuring the first transformer;
a first lead-out wiring;
a second lead-out wiring; and
an insulating layer,
wherein the first transmission/reception coil includes a first coil and a second coil,
wherein the first coil and the second coil are arranged side by side in plan view, and are connected in series with each other through the first lead-out wiring,
wherein the second transmission/reception coil includes a third coil and a fourth coil,
wherein the third coil and the fourth coil are arranged to respectively face the first coil and the second coil through the insulating layer, and are connected in series with each other through the second lead-out wiring, and
wherein the first lead-out wiring and the second lead-out wiring are respectively electrically connected to the first switch and the second switch.

3. The semiconductor device according to claim 2,
wherein the first semiconductor chip further includes a first transmission/reception circuit electrically connected to the first transmission/reception coil,
wherein the first transmission/reception circuit includes a first transmission circuit and a first reception circuit,
wherein the second semiconductor chip further includes a second transmission/reception circuit electrically connected to the second transmission/reception coil,
wherein the second transmission/reception circuit includes a second transmission circuit and a second reception circuit,
wherein the first transmission circuit is electrically connected to the first transmission/reception coil while the second reception circuit is electrically connected to the second transmission/reception coil when the first switch is turned off while the second switch is turned on, and
wherein the first reception circuit is electrically connected to the first transmission/reception coil while the second transmission circuit is electrically connected to the second transmission/reception coil when the second switch is turned off while the first switch is turned on.

4. The semiconductor device according to claim 2,
wherein the first semiconductor chip further includes a first control circuit configured to switch an “on” state and an “off” state of the first switch, and
wherein the second semiconductor chip further includes a second control circuit configured to switch an “on” state and an “off” state of the second switch.

5. The semiconductor device according to claim 1,
wherein the first switch is a first MOSFET,
wherein the second switch is a second MOSFET, and
wherein each of a gate width of the first MOSFET and a gate width of the second MOSFET is equal to or larger than 5 μm.

6. The semiconductor device according to claim 2,
wherein the third semiconductor chip includes a second transformer and a third transformer,
wherein the second transformer includes a first transmission coil and a first reception coil,
wherein the third transformer includes a second transmission coil and a second reception coil,
wherein the first transmission coil and the second transmission coil are arranged to respectively face the first reception coil and the second reception coil through the insulating layer,
wherein a signal is transmitted from the first semiconductor chip to the second semiconductor chip by the second transformer, and
wherein a signal is transmitted from the second semiconductor chip to the first semiconductor chip by the third transformer.

7. The semiconductor device according to claim 6,
wherein the first transformer, the second transformer, and the third transformer are arranged side by side such that the first transformer is positioned between the second transformer and the third transformer in plan view.

8. The semiconductor device according to claim 7,
wherein the third semiconductor chip further includes a guard ring,
wherein the guard ring surrounds the first transformer, the second transformer, and the third transformer in plan view,
wherein each of a distance between the first transformer and the second transformer and a distance between the first transformer and the third transformer is equal to or larger than 15 μm, and
wherein each of a distance between the first transformer and the guard ring, a distance between the second transformer and the guard ring, and a distance between the third transformer and the guard ring is equal to or larger than 50 μm.

9. The semiconductor device according to claim 6,
wherein the number of coil windings of the first transformer is larger than the number of coil windings of the second transformer and the number of coil windings of the third transformer.

10. The semiconductor device according to claim 7,
wherein the number of coil windings of the first transformer is equal to or smaller than 1.2 times the number of coil windings of the second transformer and 1.2 times the number of coil windings of the third transformer.

11. The semiconductor device according to claim 6,
wherein a signal transmission mode between the first semiconductor chip and the second semiconductor chip by the first transformer is an SPI communication mode, and
wherein each of a signal transmission mode between the first semiconductor chip and the second semiconductor chip by the second transformer and a signal transmission mode between the first semiconductor chip and the second semiconductor chip by the third transformer is a PWM communication mode.

12. An inverter system comprising:
an inverter circuit including a power semiconductor element;
a first semiconductor chip;
a second semiconductor chip; and
a third semiconductor chip,
wherein one of the first semiconductor chip and the second semiconductor chip includes a first switch,
wherein the other of the first semiconductor chip and the second semiconductor chip includes a second switch,
wherein the second semiconductor chip is electrically connected to the inverter circuit,
wherein the third semiconductor chip includes a first transformer,
wherein a signal is transmitted from the first semiconductor chip to the second semiconductor chip by the first transformer when the first switch is turned off while the second switch is turned on, and
wherein a signal is transmitted from the second semiconductor chip to the first semiconductor chip by the first transformer when the second switch is turned off while the first switch is turned on
